(19) United States
(12) Patent Application Publication
(10) Pub. No.: US 2006/0163607 A1
(43) Pub. Date: Jul. 27, 2006

(54) Upside-down photo detector

(75) Inventors: Johannes Otto Voorman, Geldrop (NL); Gerben Willem De Jong, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., Eindhoven (NL)

(21) Appl. No.: 10/561,302

(22) PCT Filed: Oct. 13, 2003
(86) PCT No.: PCT/IB03/04562

§ 371 Date: Dec. 19, 2005

(30) Foreign Application Priority Data
Nov. 7, 2002 (EP) 02079655.3

(51) Int. Cl. H01L 31/109; H01L 21/302

(52) U.S. Cl. 257/184; 438/689

(57) ABSTRACT

The efficiency of photo diodes is according to a basic idea improved by using them upside-down through letting the light (20) enter via the substrate layer (1), and by using the surface layer (3) as a mirror. Then, the epitaxial layer (2) has an approximately doubled chance to convert photons to electron-hole-pairs: either during a first pass when coming from the substrate layer (1) or during a second pass after being reflected at the surface layer (3). The surface layer (3) comprises metal stripes (6,7,8) and metal mirrors (9,10) and comprises metal areas (15,16) coupled to solders bumps (4,5) for precisely mounting said photo detector on a flexible printed-circuit board. The epitaxial layer (2) and areas (17,18,19) in the epitaxial layer (2) form electrodes of a first diode, and the epitaxial layer (2) and the substrate layer (1) form electrodes of a second diode which approximately doubles said efficiency again when adding the photocurrents of both diodes. A substrate layer (1) comprising silicon-on-insulator and/or an etch stopper can be easily made thinner by removing the silicon and/or by etching until said etch stopper.

The invention relates to a photo detector for converting at least one light signal arriving via at least one invention also relates to an optical pick-up unit comprising a flexible printed-circuit board side of said photo detector.

The (PCB) and a photo detector mounted on this flexible PCB,

and to a method for producing a photo detector for converting at least one light signal arriving via at least one side of said photo detector.

Such a photo detector converts light signals into electrical signals and is produced through semiconductor technology, with an upper layer and a middle layer receiving said light signal like for example infra red light having a penetration depth of for example 20 μm or like for example blue light having a penetration depth of for example 0.3 μm, and with a lower layer forming a substrate.

A prior art photo detector is known from U.S. Pat. No. 5,097,307, which discloses said upper layer being an surface layer and said middle layer being an epitaxial layer and said lower layer being a substrate layer.

The known photo detector is disadvantageous, inter alia, due to, when converting said light into for example an electrical current, having an efficiency which gets worse for thinner epitaxial layers: photons entering the photo detector at the side of the surface layer will not all be converted to electron-hole pairs within the epitaxial layer and then disappear in the substrate layer, due to the epitaxial layer according to more advanced integrated circuit (ic) processes (like for example CQuBiC3) getting thinner and thinner. For a good efficiency, the epitaxial layer needs to have a thickness of about for example twice or thrice the penetration depth of the incoming light.

It is an object of the invention, inter alia, of providing a photo detector having a better efficiency in combination with a large bandwidth.

It is a further object of the invention, inter alia, of providing an optical pick-up unit with a photo detector having a better efficiency in combination with a large bandwidth

It is a yet further object of the invention, inter alia, of providing a method for producing a photo detector having a better efficiency in combination with a large bandwidth.

The photo detector according to the invention converts at least one light signal arriving via at least one side of said photo detector and comprises at least one substrate layer and at least one epitaxial layer and at least one surface layer, wherein said side comprises said substrate layer, with said surface layer having a mirror function for reflecting at least parts of said light signal.

By using the photo detector upside-down, said photons now enter the epitaxial layer via the substrate layer. Those photons not immediately converted into electron-hole pairs within this epitaxial layer are now reflected by (the inside of) said surface layer, and return into the epitaxial layer for getting a second chance to be converted. So, at the same thickness of the epitaxial layer, the efficiency is now for example doubled.

Compared to prior art photo detectors, in which prior art photo detectors holes needed to be made for letting the light pass through said surface layer and enter said epitaxial layer and in which prior art photo detectors reflections at (the outside of) said surface layer of the incoming light caused problems for the stability of the laser, by using the photo detector upside-down and using (the inside of) the surface layer as a mirror, no longer any holes need to be made for letting the light pass through said surface layer, and the reflections of the incoming light at the inside of the surface layer are causing less problems to the stability of the laser.

Further, due to the light now entering via the substrate layer, for example low-ohmic (low-noise) aluminum stripes can be used in the surface layer, and for example aluminum planes can be used as mirrors.

A first embodiment of the photo detector according to the invention is defined by claim 2.

By providing said surface layer with metal areas coupled to solders bumps for mounting said photo detector on a flexible PCB of an optical pick-up unit, the photo detector can be mounted precisely on the flexible PCB, and no longer needs to be housed in a package (which provides more space at the flexible PCB). The solder bumps provide small lead inductances, which smaller lead inductances allow higher frequencies and provide more stability.

A second embodiment of the photo detector according to the invention is defined by claim 3.

By selecting said substrate layer to be p-type or n-type respectively, with said epitaxial layer being n-type or p-type respectively, and with said epitaxial layer comprising at least one p-type or n-type area respectively, said epitaxial layer and said area form electrodes of a diode functioning as photo detector. Preferably, instead of one large area, said epitaxial layer comprises many small, striped areas, with the epitaxial layer at said areas being depleted, to reduce the capacitance of the photo detector.

A third embodiment of the photo detector according to the invention is defined by claim 4.

By letting said epitaxial layer and said substrate layer form electrodes of a further diode, the efficiency of the photo detector is for example doubled again, due to now two diodes cooperating. The common cathode or anode respectively of the photo-detector diode and the further diode is for example connected via low-ohmic buried stripes being n-type or p-type respectively located between substrate layer and epitaxial layer in combination with wells also being n-type or p-type respectively.

It should be observed that this further diode itself is known from prior art photo detectors, which are used non-upside-down and which comprise thicker layers, and where said further diode catches electron-hole-pairs which would otherwise contribute to so-called slow-tails in the step response. Slow tails originate from electron-hole pairs generated deep down in the silicon. These minority charge carriers have to travel a long way by means of diffusion before they reach the electrodes. Since diffusion is a relatively slow process, this journey of the minority charge carriers to the electrodes takes a relatively long time, which leads to slow tails in the step response. According to the invention, both the diode and the further diode provide results (for example currents) which can be added.

A fourth embodiment of the photo detector according to the invention is defined by claim 5.

Silicon-on-insulator is an advantageous substrate layer due to said substrate layer easily being made thinner by removing the silicon.

A fifth embodiment of the photo detector according to the invention is defined by claim 6.

Said etch stopper forms an advantageous part for a substrate layer due to said substrate layer easily being made thinner by etching said layer until said etch stopper.

Embodiments of the optical pick-up unit according to the invention and of the method according to the invention correspond with the embodiments of the photo detector according to the invention.

The invention is based upon an insight, inter alia, that incoming light to be converted into electrical current by a photo detector must reach the epitaxial layer, and is based upon a basic idea, inter alia, that instead of entering the epitaxial layer from one side, the incoming light should enter it from the other side.

The invention solves the problem, inter alia, of providing a photo detector with a better efficiency, and is advantageous, inter alia, in that the disadvantageous reflecting at (the outside of) the surface layer has been converted into an advantageous reflecting at (the inside side of) the surface layer.

These and other aspects of the invention will be apparent from and elucidated with reference to the embodiments(s) described hereinafter.

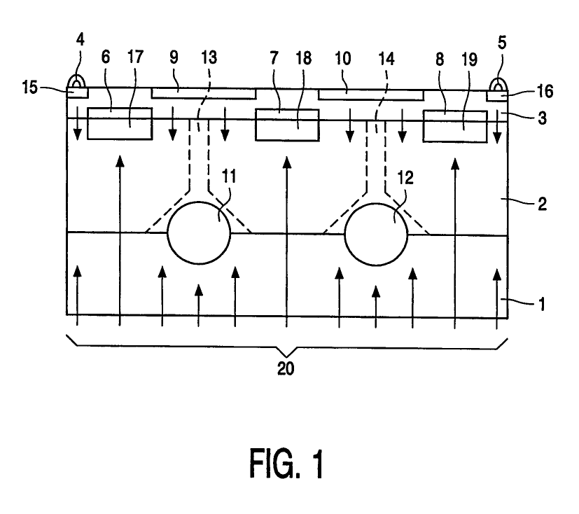

FIG. 1 illustrates in block diagram form a photo detector according to the invention.

The photo detector according to the invention shown in FIG. 1 comprises a substrate layer 1 on which an epitaxial layer 2 has been located, with an surface layer 3 being located on said epitaxial layer 2. Surface layer 3 comprises metal areas 15,16 coupled to solder bumps 4,5 and metal mirrors 9,10 and metal areas 6,7,8 located near or on the border between epitaxial layer 2 and surface layer 3. Epitaxial layer 2 comprises buried stripes 11,12 located near or on the border between epitaxial layer 2 and substrate layer 1 and comprises wells 13,14 located near said buried stripes 11,12 and between said buried stripes 11,12 and surface layer 3 and comprises shallow doped areas 17,18,19 located near said metal areas 6,7,8.

Prior art photo detectors received the light 20 from above, in other words via surface layer 3. To let this light 20 pass through said surface layer 3, holes needed to be made in the first metal layer at the level of metal areas 6,7,8 and in the second metal layer at the level of metal mirrors 9,10 and metal areas 15,16. Further, reflections of the incoming light 20 at (the outside of) said metal layers caused problems for the stability of the laser which had generated this light 20 (usually light 20 originates from a laser and arrives via reflections and focussing at an optical disk).

Further, said light 20 for example comprises infra red light having a penetration depth of for example 20 μm or for example comprises blue light having a penetration depth of for example 0.3 μm. When converting said light 20 into for example a current, the efficiency for prior art photo detectors gets worse for thinner epitaxial layers 2: photons entering the photo detector via the surface layer 3 will not all be converted to electron-hole pairs within the epitaxial layer 2 and then disappear in the substrate layer 1, due to the epitaxial layer 2 according to more advanced HF integrated circuit (ic) processes (like for example CQuBiC3) getting thinner and thinner. For a good efficiency, the epitaxial layer 2 needs to have a thickness of about for example twice or thrice the penetration depth of the incoming light 20.

To provide a photo detector having an improved efficiency, inter alia, the photo detector is used upside-down through letting the light 20 enter via the substrate layer 1, whereby the metal areas 6,7,8,15,16 and mirrors 9,10 are used as a mirror. Then, the epitaxial layer 2 has an approximately doubled chance to convert photons to electron-hole-pairs: either during a first pass when coming from the substrate layer 1 or during a second pass after being reflected at the metal areas 6,7,8,15,16 and mirrors 9,10. So, at the same thickness of the epitaxial layer 2, the efficiency is now for example approximately doubled.

Compared to said prior art photo detectors, no longer any holes need to be made in said metal layers for letting the light pass, and the reflections of the incoming light 20 at the inside of the metal areas 6,7,8,15,16 and mirrors 9,10 are causing less problems to the stability of the laser. Due to the light 20 now entering via the substrate layer 1, for example low-ohmic (low-noise) aluminum stripes 6,7,8 can be used, and for example aluminum planes 9,10 can be used as mirrors.

Solder bumps 4,5 coupled to metal areas 15,16 in surface layer 3 allow said photo detector to be mounted precisely on a flexible printed-circuit board (PCB) of an optical pick-up unit, and the photo detector no longer needs to be housed in a package (which provides more space at the flexible PCB). The solder bumps 4,5 provide small lead inductances, which smaller lead inductances allow higher frequencies and provide more stability.

Said substrate layer 1 is for example p-type (or n-type), with said epitaxial layer 2 being n-type (or p-type), and with said epitaxial layer 2 comprising at least one shallow p-type (or n-type) doped area 17,18,19. Then said epitaxial layer 2 and said shallow doped area 17,18,19 form electrodes of a diode functioning as photo detector. Preferably, instead of one large area 17,18,19, said epitaxial layer 2 comprises many small, striped areas 17,18,19, with the epitaxial layer 2 at said areas 17,18,19 being depleted, to reduce the capacitance of the photo detector.

Said epitaxial layer 2 and said substrate layer 1 may form electrodes of a further diode, in which case the efficiency of the photo detector is for example doubled again, due to now two diodes cooperating (with their currents for example being added). The further diode and the photo-detector diode are both for example connected via low-ohmic buried stripes 11,12 being n-type (or p-type) located between substrate layer 1 and epitaxial layer 2. Both diodes have a common cathode (or anode) comprising of the epitaxial layer 2, the buried stripes 11,12 and the wells 13,14.

Said substrate layer 1 can be silicon-on-insulator in which case said substrate layer 1 can easily be made thinner by removing the silicon. And/or said substrate layer 1 may comprise an etch stopper in which case said substrate layer 1 can easily be made thinner by etching said layer until said etch stopper.

In case of the epitaxial laxer 2 being n-type with a light doping profile, wells 13,14 are n-type with a little heavier doping profile, buried stripes 11,12 are n-type with a more heavier doping profile, and the center of buried stripes 11,12 is n-type with the heaviest doping profile. As a result, an electric field can be created (based upon doping profile gradients) inside the photo detector for accelerating the (minority) holes and therefore enhancing the bandwidth of said photo detector.

The buried stripes 11,12 may consist out of a combination of standard buried stripes (BN or BP) and deep buried stripes (BND or BPD), or they may consist out of deep buried stripes (BND or BPD) only, or they may consist out of standard buried stripes (BN or BP) only.

The method according to the invention for producing a photo detector (for converting at least one light signal 20 arriving via at least one side of said photo detector) comprises the steps of locating at least one epitaxial layer 2 on at least one substrate layer 1 and of locating at least one surface layer 3 on said epitaxial layer 2 (wherein said side comprises said substrate layer 1) and comprises the step of giving said surface layer 3 a mirror function for reflecting at least parts of said light signal 20. Thereby it is assumed that substrate layer 1 is not too thick.

According to embodiments, if substrate layer 1 is too thick, it should be made thinner. This could be done for example by either etching until an etch stopper, with said substrate layer 1 comprising said etch stopper, or by removing silicon, with said substrate layer 1 comprising silicon-on-insulator.

So, the processing can start from silicon-on-insulator (SOI) wafers with one top layer (using a single photo diode only) or with two top layers (for two photo diodes back-to-back with the epitaxial layer being for example a common cathode). Normal processing is carried out, for example a CBiCMOS process. Finally, post-processing is done, the silicon at the backside is removed, and a transparent plastic may cover the integrated circuit (ic) after mounting (upside-down). Alternatively to the silicon-on-insulator (SOI) wafers, the wafer may be thinned using silicon-on-anything (SOA) techniques, it may be attached to a second wafer and the optical window may be opened by etching until said etch stopper.

The expression “for” in for example “for converting” and “for reflecting” and “for mounting” does not exclude that other functions are performed as well, simultaneously or not. And the expression “said surface layer having a mirror function” does not exclude that other functions are performed as well, like for example interconnection functions or insulating functions. The expressions “X coupled to Y” and “a coupling between X and Y” and “coupling/couples X and Y” etc. do not exclude that an element Z is in between X and Y. The expressions “P comprises Q” and “P comprising Q” etc. do not exclude that an element R is comprises/included as well. The terms “a” and “an” do not exclude the possible presence of one or more pluralities.

The invention is based upon an insight, inter alia, that incoming light to be converted into electrical current by a photo detector must reach the epitaxial layer 2, and is based upon a basic idea, inter alia, that instead of entering the epitaxial layer 2 from one side, the incoming light should enter it from the other side.

The invention solves the problem, inter alia, of providing a photo detector with a better efficiency, and is advantageous, inter alia, in that the disadvantageous reflecting at (the outside of) the surface layer 3 has been converted into an advantageous reflecting at (the inside side of) the surface layer 3.

1. Photo detector for converting at least one light signal arriving via at least one side of said photo detector and comprising at least one substrate layer and at least one epitaxial layer and at least one surface layer, wherein said side comprises said substrate layer, with said surface layer having a mirror function for reflecting at least parts of said light signal.

2. Photo detector according to claim 1, wherein said surface layer comprises metal areas coupled to solders bumps for mounting said photo detector on a flexible printed-circuit board of an optical pick-up unit.

3. Photo detector according to claim 2, wherein said substrate layer is p-type or n-type respectively, said epitaxial layer is n-type or p-type respectively, with said epitaxial layer comprising at least one p-type or n-type area respectively, whereby said epitaxial layer and said area form electrodes of a diode.

4. Photo detector according to claim 3, wherein said epitaxial layer and said substrate layer form electrodes of a further diode.

5. Photo detector according to claim 2, wherein said substrate layer comprises silicon-on-insulator.

6. Photo detector according to claim 2, wherein said substrate layer comprises an etch stopper.

7. Optical pick-up unit comprising a flexible printed-circuit board and a photo detector mounted on this flexible printed-circuit board, which photo detector converts at least one light signal arriving via at least one side of said photo detector and comprises at least one substrate layer and at least one epitaxial layer and at least one surface layer, wherein said side comprises said substrate layer, with said surface layer having a mirror function for reflecting at least parts of said light signal and comprising metal areas coupled to solders bumps for mounting said photo detector on said flexible printed-circuit board.

8. Method for producing a photo detector for converting at least one light signal arriving via at least one side of said photo detector, which method comprises the steps of locating at least one epitaxial layer on at least one substrate layer and of locating at least one surface layer on said epitaxial layer, wherein said side comprises said substrate layer, with said method comprising the step of giving said surface layer a mirror function for reflecting at least parts of said light signal.

9. Method according to claim 8, wherein said method comprises the step of thinning said substrate layer.

10. Method according to claim 9, wherein said step of thinning either comprises a substep of etching until an etch stopper, with said substrate layer comprising said etch stopper, or comprises a substep of removing silicon, with said substrate layer comprising silicon-on-insulator.
